(19) United States
(12) Patent Application Publication
(10) Pub. No.: US 2011/0239423 A1
(43) Pub. Date: Oct. 6, 2011

(54) MANUFACTURING METHOD OF PIEZOELECTRIC ACTUATOR

(75) Inventors: Masato GODO, Matsumoto-shi (JP); Takumi YAMAOKA, Chino-shi (JP)

(73) Assignee: SEIKO EPSON CORPORATION, Tokyo (JP)

(21) Appl. No.: 13/079,257

(22) Filed: Apr. 4, 2011

(30) Foreign Application Priority Data
Apr. 6, 2010 (JP) 2010-087596

(51) Int. Cl. H01L 41/22

(52) U.S. Cl. 29/25.35

(57) ABSTRACT

After the piezoelectric element forming process, in the etching process, etching is performed on a portion of at least the vibrating plate between the lead-out electrodes formed afterwards in the lead-out electrode forming process in a condition where the upper electrode film etching residual is removed and the vibrating plate is not removed. In the piezoelectric element forming process, even if the upper electrode film etching residual is generated between the lead-out electrodes, the upper electrode film etching residual is divided up due to the etching and it is possible to maintain insulation between the lead-out electrodes formed in the upper electrode film etching residual. Accordingly, it is possible to obtain the manufacturing method of the piezoelectric actuator which reduces driving defects in the piezoelectric actuator generated by short circuiting between the lead-out electrodes.

The entire disclosure of Japanese Patent Application No. 2010-087596, filed Apr. 6, 2010 is expressly incorporated by reference herein.

### BACKGROUND

1. Technical Field

The present invention relates to a manufacturing method of a piezoelectric actuator provided with a piezoelectric element, which has a piezoelectric body formed from an individual electrode and a piezoelectric material, and a lead-out electrode connected to each individual electrode.

2. Related Art

As a piezoelectric actuator, there is known a piezoelectric actuator provided with a piezoelectric element, which has a lower electrode, a piezoelectric body and an upper electrode, and a lead-out electrode connected to each of the electrodes of the piezoelectric element. As a piezoelectric element, there is a piezoelectric element configured by interposing a piezoelectric body formed from a piezoelectric material provided with an electromechanical transduction function, for example, crystallized piezoelectric ceramics or the like, between two electrodes of a lower electrode and an upper electrode.

As a manufacturing method of a piezoelectric actuator, there is known a manufacturing method where a laminated lower electrode film, piezoelectric layer and upper electrode film are patterned using dry etching such as reactive ion etching, ion milling or the like, a piezoelectric element having a lower electrode, a piezoelectric body and an upper electrode is formed, and then a lead-out electrode is formed for each of the upper electrodes which are individual electrodes (for example, JP-A-2009-255526 (p.9, FIG. 6)).

When particles are attached to the upper electrode film before dry etching or during dry etching, a portion of the lower electrode film, the piezoelectric layer and the upper electrode film where the particles are attached is not etched and remains.

Among the lower electrode film, the piezoelectric layer and the upper electrode film, which remain in a portion other than the formation portion of the piezoelectric element, the etching residual which spans between the lead-out electrodes formed thereafter, generates short circuiting between the lead-out electrodes via the upper electrode film when the lead-out electrodes are formed. Accordingly, the insulation between the lead-out electrodes is not maintained and driving defects are generated in the piezoelectric actuator due to the short circuiting.

### SUMMARY

An advantage of some aspects of the invention is that it is possible to be realized as the embodiments and applied examples below.

### Application 1

A manufacturing method of a piezoelectric actuator provided with a lead-out electrode led-out from each of a piezoelectric element, which has either of a lower electrode or an upper electrode provided as an individual electrode, and the individual electrode including a lower electrode film forming process which forms a lower electrode film on a substrate, a piezoelectric layer forming process which forms a piezoelectric layer on the lower electrode film, an upper electrode film forming process which forms an upper electrode film on the piezoelectric layer, a piezoelectric element forming process which selectively performs etching on the piezoelectric layer and the lower electrode film or the upper electrode film and forms a piezoelectric element with a piezoelectric body and either of the lower electrode or the upper electrode provided as an individual electrode, an etching process which performs etching of a portion of at least the substrate between the lead-out electrodes in a condition where the upper electrode film is removed and the substrate is not removed after the piezoelectric element forming process, and a lead-out electrode forming process which forms the lead-out electrode led-out from each individual electrode after the etching process.

According to the applied example, in the etching process, etching of a portion of at least the substrate between the lead-out electrodes formed in the lead-out electrode forming process is performed in a condition where the upper electrode film is removed and the substrate is not removed. In the piezoelectric element forming process, even if there is etching residual including the upper electrode film between the lead-out electrodes, the upper electrode film is divided up due to the etching and insulation is maintained between the lead-out electrodes formed on the upper electrode film. Accordingly, it is possible to obtain a manufacturing method of a piezoelectric actuator which reduces driving defects in the piezoelectric actuator generated by short circuiting between the lead-out electrodes.

### Application 2

A manufacturing method of a piezoelectric actuator where, in the etching process of the manufacturing method of the piezoelectric actuator described above, etching between the lead-out electrodes is performed along the lead-out electrodes and a slit is formed in the substrate.

In the applied example, since a slit between the lead-out electrodes is formed along the lead-out electrodes, even when there is etching residual including the upper electrode film in any position between the lead-out electrodes, the upper electrode film is divided up and insulation is maintained between the lead-out electrodes. Accordingly, it is possible to obtain a manufacturing method of a piezoelectric actuator with fewer driving defects in the piezoelectric actuator generated by short circuiting between the lead-out electrodes.

### Application 3

A manufacturing method of a piezoelectric actuator where, in the piezoelectric element forming process of the manufacturing method of the piezoelectric actuator described above, the lower electrode is formed on the substrate as a common electrode and etching is selectively performed on the piezoelectric layer and the upper electrode film, whereby the piezoelectric element is formed with a piezoelectric body and the upper electrode provided as an individual electrode.

In the applied example, it is possible to obtain a manufacturing method of a piezoelectric actuator having the above effects in regard to a piezoelectric actuator with the lower electrode formed on a vibrating plate as the common electrode and the upper electrode formed on the piezoelectric body as the individual electrode.

### BRIEF DESCRIPTION OF THE DRAWINGS

The invention will be described with reference to the accompanying drawings, wherein like numbers reference like elements.

FIG. 1 is a schematic diagram illustrating an example of an ink jet recording apparatus.

FIG. 2 is an exploded partial perspective diagram illustrating an ink jet recording head.

FIG. 3A is a partial planar diagram of the ink jet recording head.

FIG. 3B is a cross-sectional diagram taken along a line IIIB-IIIB in FIG. 3A.

FIG. 4 is a flow chart diagram describing a manufacturing method of an ink jet recording head.

FIGS. 5A to 5D are cross-sectional diagrams in a longitudinal direction of a pressure generating chamber illustrating a manufacturing method of an ink jet recording head.

FIGS. 6A to 6D are cross-sectional diagrams in a longitudinal direction of a pressure generating chamber illustrating a manufacturing method of an ink jet recording head.

FIGS. 7A to 7C are cross-sectional diagrams in a longitudinal direction of a pressure generating chamber illustrating a manufacturing method of an ink jet recording head.

FIGS. 8A to 8C are cross-sectional diagrams in a longitudinal direction of a pressure generating chamber illustrating a manufacturing method of an ink jet recording head.

FIGS. 9A and 9B are cross-sectional diagrams in a longitudinal direction of a pressure generating chamber illustrating a manufacturing method of an ink jet recording head.

FIGS. 10A to 10C are cross-sectional diagrams in a longitudinal direction of a pressure generating chamber illustrating a manufacturing method of an ink jet recording head.

FIG. 11 is a partial planar diagram of a state of FIG. 6D in a case where particles are attached.

FIGS. 12A and 12B are partial cross-sectional diagrams of a state of FIG. 6D in a case where a particle is attached, where FIG. 12A is a partial cross-sectional diagram taken along a line XIIA-XIIA of FIG. 11 and FIG. 12B is a partial cross-sectional diagram taken along a line XIIB-XIIB of FIG. 11.

FIGS. 13A and 13B are partial cross-sectional diagrams of a state of FIG. 7A in a case where a particle is attached, where FIG. 13A is a partial cross-sectional diagram taken along a line XIIIA-XIIIA of FIG. 11 and FIG. 13B is a partial cross-sectional diagram taken along a line XIIIB-XIIIB of FIG. 11.

FIGS. 14A and 14B are partial cross-sectional diagrams of states of FIGS. 7C and 8A in a case where a particle is attached, where FIG. 14A is a partial cross-sectional diagram taken along a line XIVA-XIVA of FIG. 11 and FIG. 14B is a partial cross-sectional diagram taken along a line XIVB-XIVB of FIG. 11.

FIGS. 15A and 15B are partial cross-sectional diagrams of a state of FIG. 8B in a case where a particle is attached, where FIG. 15A is a partial cross-sectional diagram taken along a line XVA-XVA of FIG. 11 and FIG. 15B is a partial cross-sectional diagram taken along a line XVB-XVB of FIG. 11.

FIGS. 16A and 16B are partial cross-sectional diagrams of a state of FIG. 8C in a case where a particle is attached, where FIG. 16A is a partial cross-sectional diagram taken along a line XVIA-XVIA of FIG. 11 and FIG. 16B is a partial cross-sectional diagram taken along a line XVIB-XVIB of FIG. 11.

### DESCRIPTION OF EXEMPLARY EMBODIMENTS

Below, an embodiment is described in detail based on the diagrams.

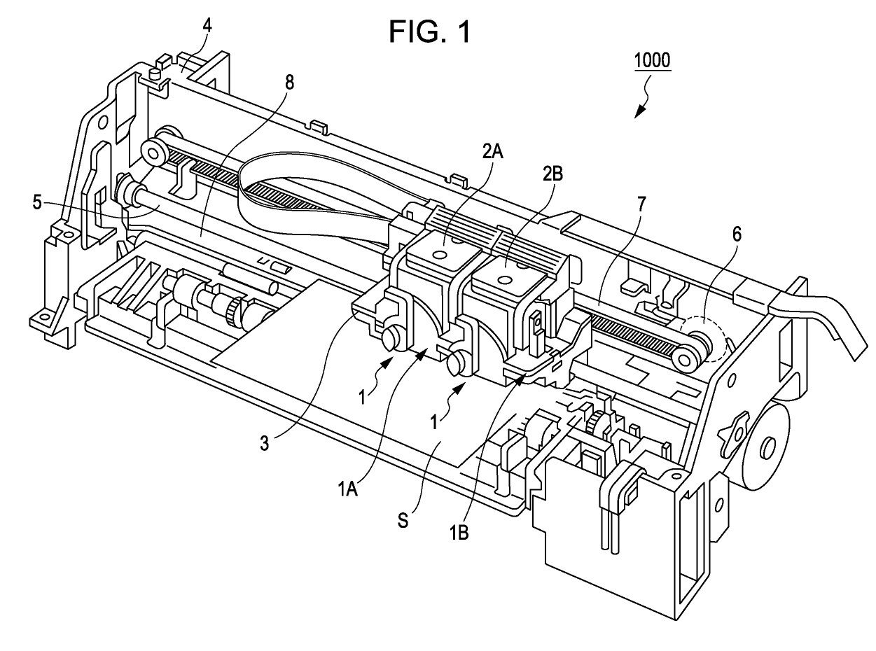

FIG. 1 is a schematic diagram illustrating an example of an ink jet recording apparatus 1000 as a liquid ejecting apparatus provided with an ink jet recording head 1 as a liquid ejecting head provided with a piezoelectric actuator.

As shown in FIG. 1, the ink jet recording apparatus 1000 is provided with recording head units 1A and 1B.

In the recording head units 1A and 1B, cartridges 2A and 2B which configure ink supply units are provided to be able to be attached and detached, and a carriage 3 with the recording head units 1A and 1B mounted thereon is provided to be able to freely move in an axial direction on a carriage axis 5 attached to an apparatus main body 4.

The recording head units 1A and 1B each eject, for example, a black ink composition and a color ink composition. In addition, by transferring the driving force of a driving motor 6 to the carriage 3 via a plurality of gears (not shown) and a timing belt 7, the carriage 3 with the recording head units 1A and 1B mounted thereon is moved along the carriage axis 5. On the other hand, in the apparatus main body 4, a platen 8 is provided along the carriage axis 5, and a recording sheet S, which is a recording medium such as paper or the like fed by a paper feeding roller or the like (not shown), is transported on the platen 8.

The recording head units 1A and 1B are provided at positions where the ink jet recording heads 1 face the recording sheet S.

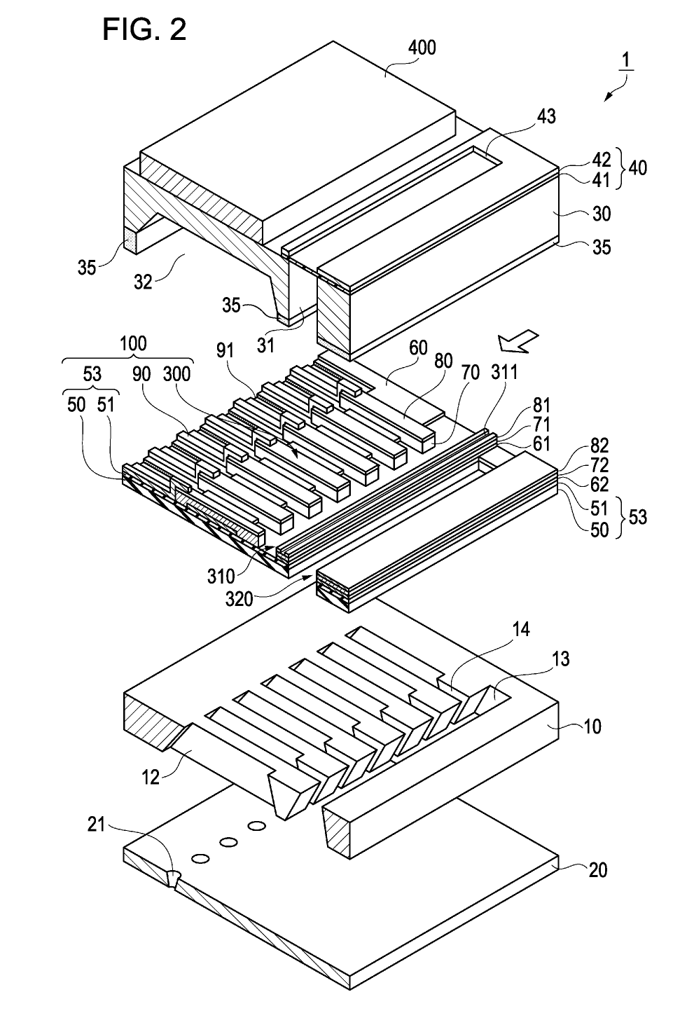

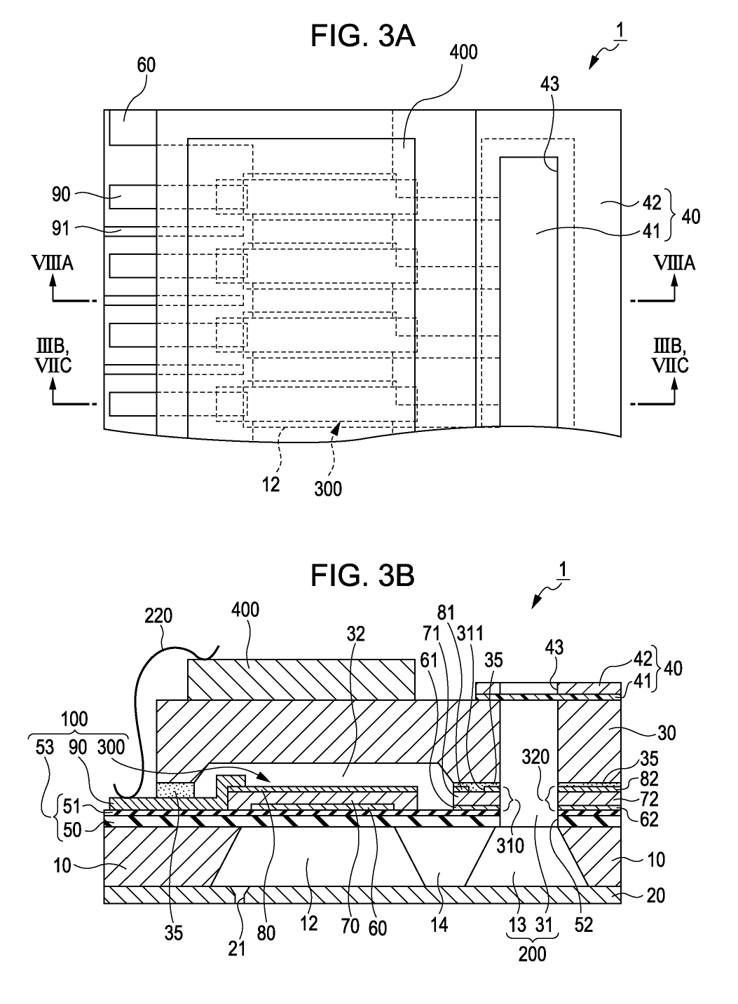

In FIG. 2, an exploded partial perspective diagram illustrating the ink jet recording head 1 is shown. The shape of the ink jet recording head 1 is substantially rectangular, and FIG. 2 is an exploded partial perspective diagram cut along a surface perpendicular to a longitudinal direction of the ink jet recording head 1 (in a direction of a white arrow in the diagram). In FIG. 3A, a partial planar diagram of the ink jet recording head 1 is shown, and in FIG. 3B, a cross-sectional diagram taken along a line IIIB-IIIB is shown.

In FIGS. 2 to 3B, the ink jet recording head 1 is provided with a flow path forming substrate 10, a nozzle plate 20, a joining substrate 30, a compliance substrate 40 and a driving IC 400.

The flow path forming substrate 10, the nozzle plate 20 and the joining substrate 30 are stacked so that the flow path forming substrate 10 is interposed between the nozzle plate 20 and the joining substrate 30, and the compliance substrate 40 is formed on the joining substrate 30. The driving IC 400 is mounted on the joining substrate 30.

The flow path forming substrate 10 is formed from a single crystal silicon plate with a plane orientation (110). In the flow path forming substrate 10, a plurality of pressure generating chambers 12 is formed in a row. The cross-sectional shape perpendicular to the longitudinal direction of the pressure generating chambers 12 of the ink jet recording head 1 is a trapezoidal shape and the pressure generating chambers 12 are formed to be long in a width direction of the ink jet recording head 1.

Also, an ink supply path 13 is formed at one end in a width direction of the pressure generating chambers 12 in the flow path forming substrate 10, and the ink supply path 13 and the pressure generating chambers 12 are communicated via communication sections 14 provided for each of the pressure generating chambers 12. The communication sections 14 are formed to have a narrower width than the pressure generating chambers 12, and flow path resistance of ink flowing into the pressure generating chambers 12 from the communication sections 14 is maintained to be constant.

In the nozzle plate 20, nozzle openings 21 are provided which communicate with the vicinity of the end portion of each of the pressure generating chambers 12 on a side opposite to the ink supply path 13.

In addition, the nozzle plate 20 is formed with a thickness of, for example, 0.01 to 1 mm from glass ceramics, a single crystal silicon substrate, stainless steel or the like.

The flow path forming substrate 10 and the nozzle plate 20 are fixed by an adhesive, a heat adhesion film or the like.

An elastic film 50 is formed on a surface facing the surface of the flow path forming substrate 10 to which the nozzle plate 20 is fixed. The elastic film 50 is formed from a film including silicon oxide.

An insulating film 51 is formed from an oxide film on the elastic film 50 of the flow path forming substrate 10. In addition, on the insulating film 51, a lower electrode 60, a piezoelectric body 70 with a perovskite structure, and an upper electrode 80 are formed to configure a piezoelectric element 300. Here, the piezoelectric element 300 is a portion including the lower electrode 60, the piezoelectric body 70 and the upper electrode 80.

In general, either one of the electrodes of the piezoelectric element 300 is set as a common electrode and the other electrode is set as an individual electrode, and are configured by being patterned for each of the pressure generating chambers 12 along with the piezoelectric body 70. Furthermore, here, a portion which is configured from either one of the electrodes which has been patterned and the piezoelectric body 70 and generates piezoelectric strain due to a voltage being applied to both electrodes is referred to as a piezoelectric active portion.

In addition, in the embodiment, the lower electrode 60 is set as the common electrode of the piezoelectric element 300 and the upper electrode 80 is set as the individual electrode of the piezoelectric element 300. However, there are no obstacles to reversing this to suit the driving circuits or wiring. In either case, the piezoelectric active portion is formed for each of the pressure generating chambers 12.

In FIGS. 2 to 3B, in the respective upper electrodes 80 which configure the respective piezoelectric elements 300 in this manner, lead-out electrodes 90 are formed.

Here, the combination of the piezoelectric element 300 with the elastic film 50 and the insulating film 51, which generate displacement due to driving of the piezoelectric element 300 (these two films are referred to as a vibrating plate 53), and the lead-out electrodes 90 is referred to as a piezoelectric actuator 100. The lower electrode 60 is formed on the vibrating plate 53 which is a substrate.

Slits 91 are formed in between the lead-out electrodes 90. The slits 91 are formed up to the insulating film 51 or the elastic film 50 and are formed in a plurality between each of the lead-out electrode 90. Also, the slits 91 are formed in at least a portion of the vibrating plate 53 between the adjacent lead-out electrodes 90 along the lead-out electrodes 90. In the embodiment, the slits 91 are formed from a portion where the lead-out electrodes 90 are formed on the upper electrodes 80 until a periphery of the insulating film 51 is reached. Here, the slits 91 are formed to be shallower than the thickness of the vibrating plate 53.

On the vibrating plate 53 with the joining substrate 30 attached, difference adjustment sections 310 and 320 are formed which have the same layer structure as the piezoelectric element 300.

The difference adjustment section 310 is formed at a position between the ink supply path 13 and the piezoelectric element 300, and the difference adjustment section 320 is formed at a position facing the difference adjustment section 310 with the ink supply path 13 interposed therebetween.

The difference adjustment section 310 is configured by a lower electrode film 61, a piezoelectric layer 71 and an upper electrode film 81, and the difference adjustment section 320 is configured by a lower electrode film 62, a piezoelectric layer 72 and an upper electrode film 82.

Here, in the upper electrode film 81 of the difference adjustment section 310, a slit 311 for reducing stress is formed in the longitudinal direction of the ink jet recording head 1.

The joining substrate 30 is joined by an adhesive 35 onto the flow path forming substrate 10 with the piezoelectric element 300 formed thereon.

The joining substrate 30 has a piezoelectric element holding section 32 which is capable of sealing a space in a region facing the piezoelectric element 300 in a state where a space is secured to an extent that the movement of the piezoelectric element 300 is not hindered. The piezoelectric element holding section 32 is provided corresponding to the row of the pressure generating chambers 12.

In addition, in the embodiment, the piezoelectric element holding section 32 is provided integrally in a region corresponding to the row of the pressure generating chambers 12, but the piezoelectric element holding section 32 may be provided independently for each of the piezoelectric elements 300. As a material for the joining substrate 30, for example, there is glass, ceramic materials, metals, resins or the like, but it is preferable if the joining substrate 30 is formed by a material with substantially the same rate of thermal expansion as the flow path forming substrate 10. In the embodiment, the joining substrate 30 is formed using a single crystal silicon substrate which is the same material as the flow path forming substrate 10.

Also, in the joining substrate 30, a reservoir section 31 is provided in a region corresponding to the ink supply path 13 of the flow path forming substrate 10. The reservoir section 31 is provided along the row of the pressure generating chambers 12 in the thickness direction of the joining substrate 30 and communicates with the ink supply path 13 of the flow path forming substrate 10 by a through hole 52, thus configuring a manifold 200 which is an ink chamber shared by each of the pressure generating chambers 12.

Also, on the joining substrate 30, a wiring pattern is provided which is connected to external wiring (not shown) and supplies driving signals. In addition, driving ICs 400 which are semiconductor integrated circuits (IC) for driving each of the piezoelectric elements 300 are mounted on the wiring pattern.

The driving signals include, for example, driving signals for driving the driving ICs 400 such as driving power signals as well as various control signals such as serial signals (SI). The wiring pattern is configured by a plurality of wiring supplying the respective signals.

The lower electrode 60 is formed in a region facing the pressure generating chambers 12 in a longitudinal direction of the pressure generating chambers 12 and is provided continuously in the region corresponding to the plurality of pressure generating chambers 12. Also, the lower electrode 60 extends until the outside of the row of the pressure generating chambers 12.

The lead-out electrodes 90 are connected in the vicinity of one end of the upper electrode 80. In addition, the driving ICs 400 and the respective lead-out electrodes 90 extending from the respective piezoelectric elements 300 are each electrically connected by connection wires 220 formed from, for example, a conductive wire such as bonding wire. Also, in the same manner, the driving ICs 400 and the lower electrode 60 are electrically connected by connection wires (not shown).

Furthermore, the compliance substrate 40 formed from a sealing film 41 and a fixing plate 42 is joined onto the joining substrate 30. Here, the sealing film 41 is formed from a material with flexibility and low rigidity (for example, a polyphenylene sulfide (PPS) film with a thickness of 6 μm) and due to the sealing film 41, one surface of the reservoir section 31 is sealed. The fixing plate 42 is formed from a hard material such as metal (for example, stainless steel (SUS) with a thickness of 30 μm or the like). Since a region of the fixing substrate 42 facing the manifold 200 becomes an opening section 43 which has been completely removed in a thickness direction, one surface of the manifold 200 is only the sealing film 41 having flexibility.

In the ink jet recording head 1, after ink is input from an ink supply unit and the inner portion is filled up by ink from the manifold 200 until it reaches the nozzle openings 21, a voltage is applied between the respective lower electrodes 60 and the upper electrodes 80 corresponding to the pressure generating chambers 12 according to recording signals from the driving ICs 400. Due to the applied voltage, the elastic film 50 and the piezoelectric body 70 are bent and deformed and pressure inside of each of the pressure generating chambers 12 is increased, whereby ink droplets are discharged from the nozzle openings 21.

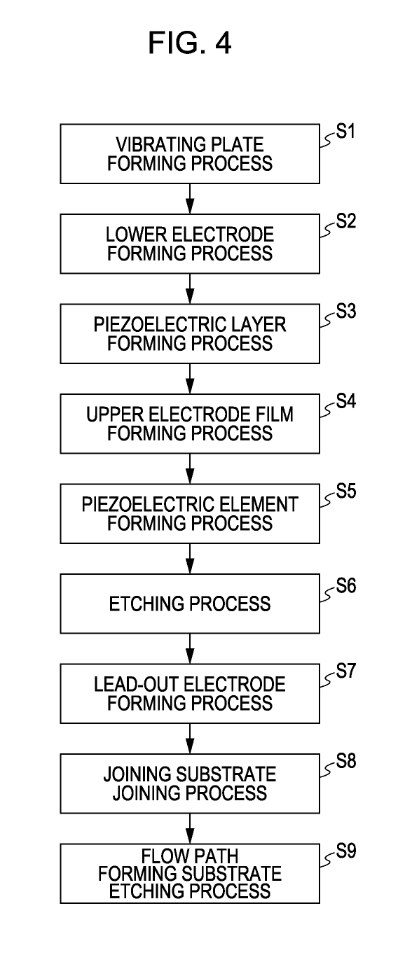

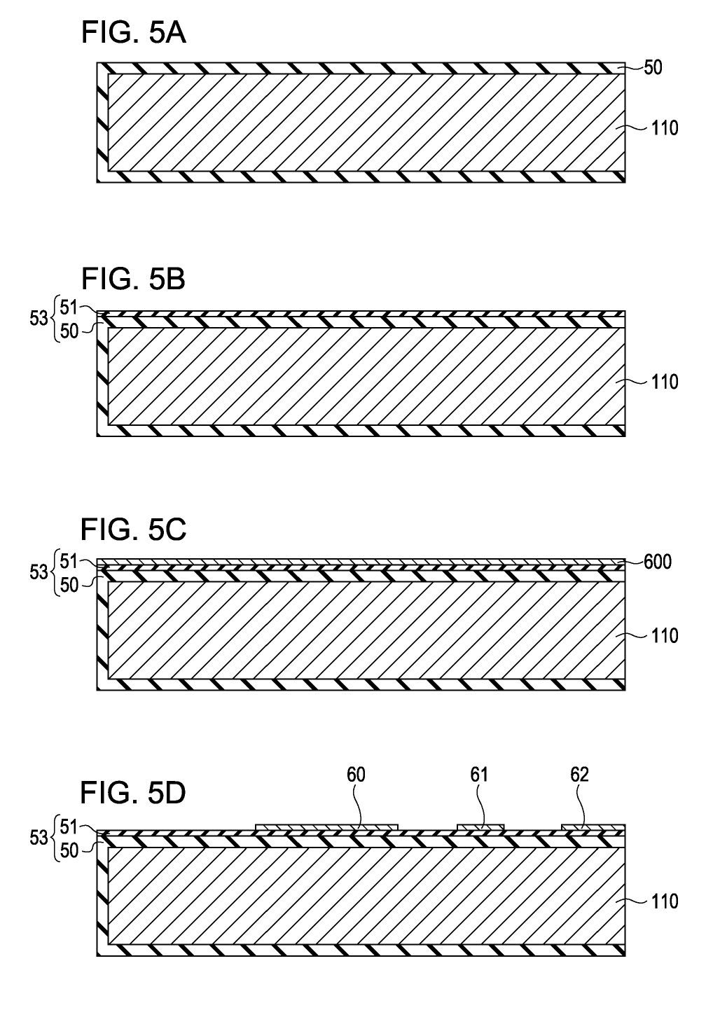

Below, a manufacturing method of the ink jet recording head 1 centered on a manufacturing method of the piezoelectric actuator 100 of the embodiment will be described with reference to FIGS. 4 to 10C. FIG. 4 is a flow chart diagram describing the manufacturing method of the ink jet recording head 1, and FIGS. 5A to 10C are cross-sectional diagrams in a longitudinal direction of the pressure generating chambers 12.

The ink jet recording head 1 is obtained by forming a plurality of the ink jet recording heads 1 in a wafer state and then separating each of the ink jet recording heads 1. FIGS. 5A to 10C show a portion of a cross-section diagram of the forming process of the ink jet recording head 1.

In FIG. 4, the manufacturing method of the ink jet recoding head 1 includes step 1 (S1) which is a vibrating plate forming process, step 2 (S2) which is a lower electrode forming process, step 3 (S3) which is a piezoelectric layer forming process, step 4 (S4) which is an upper electrode film forming process, step 5 (S5) which is a piezoelectric element forming process, step 6 (S6) which is an etching process, step 7 (S7) which is a lead-out electrode forming process, step 8 (S8) which is a joining substrate joining process, and step 9 (S9) which is a flow path forming substrate etching process.

Here, the manufacturing method of the piezoelectric actuator 100 includes the vibrating plate forming process (S1), the lower electrode forming process (S2), the piezoelectric layer forming process (S3), the upper electrode film forming process (S4), the piezoelectric element forming process (S5), the etching process (S6), and the lead-out electrode forming process (S7).

The vibrating plate forming process (S1) is shown in FIGS. 5A and 5B.

In FIG. 5A, a flow path forming substrate wafer 110 which is a silicon wafer is thermally oxidized in a diffusion furnace at approximately 1100° C., and on the surface thereof, the elastic film 50 including silicon dioxide is formed. For example, as the flow path forming substrate wafer 110, a silicon wafer, which has high rigidity and is relatively thick with a thickness of approximately 625 μm, can be used.

In FIG. 5B, on the elastic film 50 on one surface side of the flow path forming substrate wafer 110, an insulating film 51 formed from zirconium oxide (ZrO₂) is formed. Specifically, on the elastic film 50, the insulating film 51 is formed from zirconium oxide by, for example, forming a zirconium (Zr) layer using a sputtering method or the like, and then thermally oxidizing the zirconium layer, for example, in a diffusion furnace at 500 to 1200° C. The vibrating plate 53 is formed by the elastic film 50 and the insulating film 51.

The vibrating plate may be a single layer structure or may be configured from materials other than silicon dioxide or zirconium oxide.

The lower electrode forming process (S2) is shown in FIGS. 5C and 5D.

In FIG. 5C, a lower electrode film 600 formed from platinum (Pt), iridium (Ir) or the like is formed over the entire surface of the insulating film 51. The lower electrode film 600 may be a laminate structure. For example, it is possible to use a laminate structure where platinum and iridium are laminated.

After this, in FIG. 5D, the lower electrode 60 can be obtained by patterning into a predetermined shape. At this time, the lower electrode film 61 and 62 of the difference adjustment sections 310 and 320 shown in FIGS. 2 to 3B are also formed.

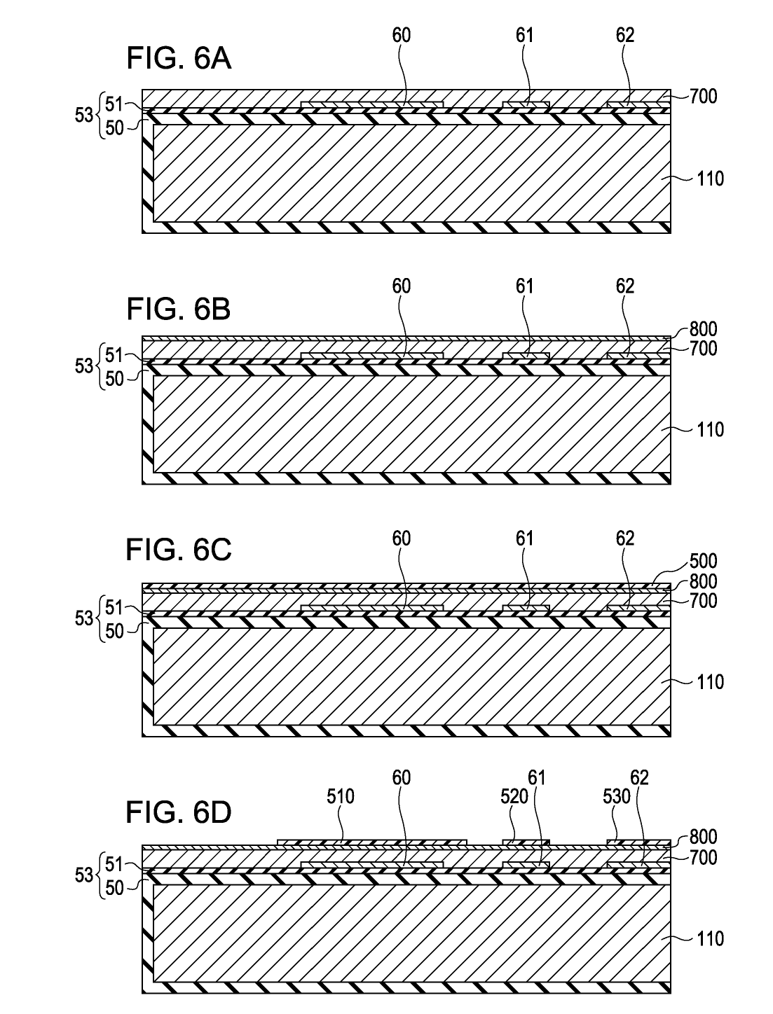

In the piezoelectric layer forming process (S3) of FIG. 6A, a piezoelectric layer 700 is formed from a piezoelectric material on the lower electrode 60, the lower electrode film 61 and 62 and insulating film 51. As the piezoelectric material, lead zirconate titanate (PZT) can be used.

As the manufacturing method of the piezoelectric layer 700, a method commonly known as a sol-gel method can be used in which a so-called sol, where a metallic organic compound is dissolved and dispersed in a catalyst, is applied, dried and formed into a gel and then is baked at a high temperature to obtain the piezoelectric layer 700 formed from a metallic oxide.

In addition, it is not limited to a sol-gel method, and for example, a MOD (metal organic decomposition) method or the like may be used.

Describing the sol-gel method in detail, first, a sol (solution) including a metallic organic compound is applied. Next, a piezoelectric precursor film obtained by the application is heated at a predetermined temperature and dried for a predetermined period of time, so that by evaporating the solvent in the sol, the piezoelectric precursor film is dried. Then, the piezoelectric precursor film is degreased for a predetermined period of time at a predetermined temperature in air.

In addition, degreasing referred to here is a separation of the organic components of the sol film as NO₂, CO₂, H₂O and the like.

The piezoelectric precursor film is formed to a predetermined thickness by repeating the applying, drying and degreasing processes a predetermined number of times, for example, twice. By heat processing the piezoelectric precursor film using a dispersion furnace or the like, crystallization occurs and a piezoelectric film is formed. That is, by baking the piezoelectric precursor film, crystals are grown and a piezoelectric film is formed.

It is preferable if the baking temperature is approximately 650 to 850° C., and for example, the piezoelectric precursor film is baked at approximately 700° C. for 30 minutes to form the piezoelectric film. The crystals of the piezoelectric film formed under these conditions have a preferred orientation in a surface (100).

By repeating the applying, drying, degreasing and baking processes described above a plurality of times, the piezoelectric layer 700 with a predetermined thickness is formed from multiple layers of the piezoelectric film.

As the material of the piezoelectric layer 700, for example, a relaxor ferroelectric or the like may be used in which a metal such as niobium, nickel, magnesium, bismuth, yttrium or the like is added to a ferroelectric piezoelectric material such as lead zirconate titanate.

In the upper electrode film forming process (S4) of FIG. 6B, after the piezoelectric layer 700 is formed, for example, an upper electrode film 800 formed from iridium, gold (Au) or the like is formed over the entire surface of the piezoelectric layer 700. The upper electrode film 800 can be formed by a sputtering method, for example, a DC or an RF sputtering method.

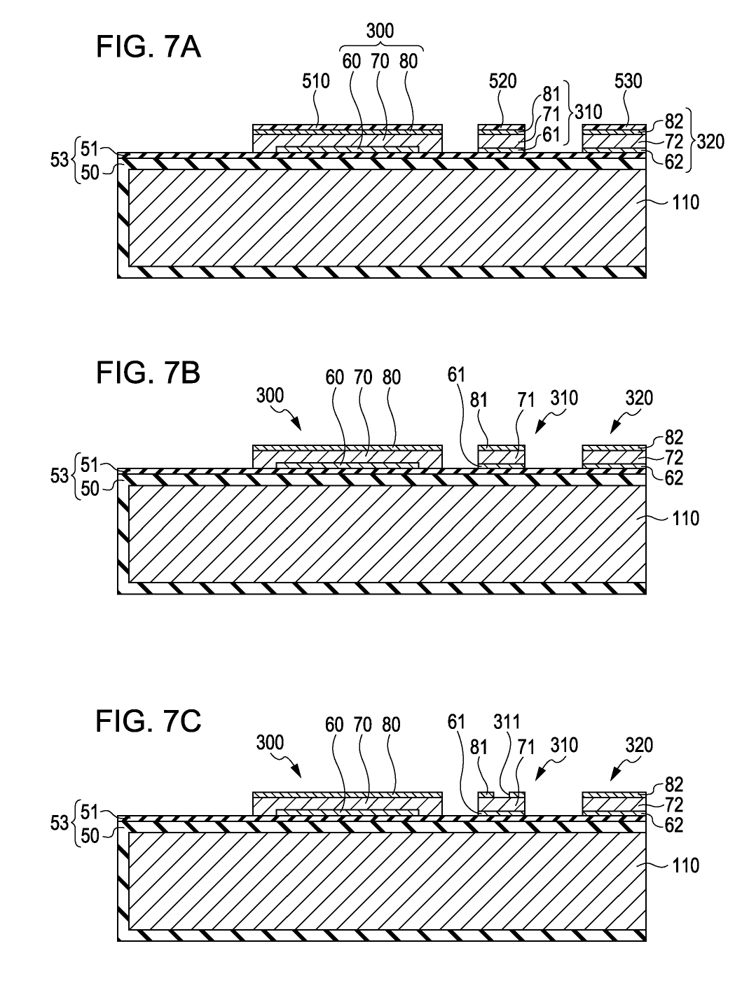

The piezoelectric element forming process (S5) is shown in FIGS. 6C, 6D, 7A and 7B.

The piezoelectric element forming process (S5) can be performed by a photolithography process. In FIG. 6C, a resist is applied on the upper electrode film 800 and a resist film 500 is formed.

In FIG. 6D, in a region where the piezoelectric element 300 and the difference adjustment sections 310 and 320 shown in FIGS. 2 to 3B are to be formed, resist films 510, 520 and 530 remain due to development.

In FIG. 7A, etching is performed on the upper electrode film 800 and the piezoelectric layer 700 using dry etching such as reactive ion etching or ion milling, and the piezoelectric element 300 and the difference adjustment sections 310 and 320 are formed.

In FIG. 7B, the resist films 510, 520 and 530 are removed.

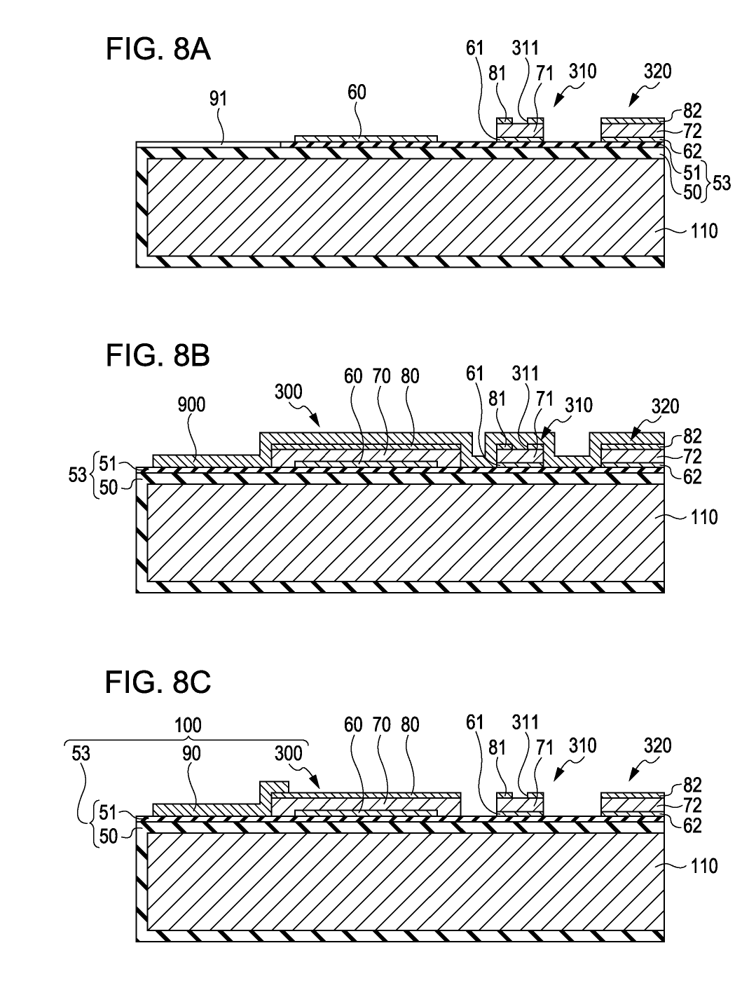

The etching process (S6) is shown in FIGS. 7C and 8A. FIG. 7C is a diagram equivalent to the cross-sectional surface VIIC-VIIC in FIG. 3A. FIG. 8A is a diagram equivalent to the cross-sectional surface VIIIA-VIIIA in FIG. 3A.

In the etching process (S6) of FIGS. 7C and 8A, the slit 91 shown in FIGS. 2 to 3B is formed. The slit 91 is formed by etching the vibrating plate 53 between the lead-out electrodes 90 to be formed later along the lead-out electrodes 90.

The etching process (S6) can be performed using a photolithography process in the same manner as the piezoelectric element forming process (S5).

In the embodiment, in the etching process (S6), it is possible to simultaneously perform the same process as the process for forming the slit 311 (shown in FIGS. 2 to 3B) for reducing stress in the upper electrode film 81 of the difference adjustment section 310. The etching is performed in a condition where the upper electrode film 81 is removed and the vibrating plate 53 is not removed.

In addition, in the etching process (S6), it is not necessary to simultaneously perform the process for forming the slit 311. For example, the slit 91 may be formed with the etching process (S6) being performed after the lead-out electrode forming process (S7). In this case, a new process is necessary.

The lead-out electrode forming process (S7) is shown in FIGS. 8B and 8C.

In FIG. 8B, a metallic layer 900 is formed over the entire surface on the flow path forming substrate wafer 110. As the main material for configuring the lead-out electrode 90, there are no particular limitations as long as it is a material with relatively high conductivity, and for example, gold, aluminium and copper may be used. Also, it may be a two layer structure or a multilayer structure with NiCr used as a base layer.

In FIG. 8C, the lead-out electrode 90 is formed by, for example, patterning the metallic layer 900 for each of the upper electrodes 80 which are the individual electrodes of the piezoelectric elements 300 via a mask pattern (not shown) formed from a resist or the like.

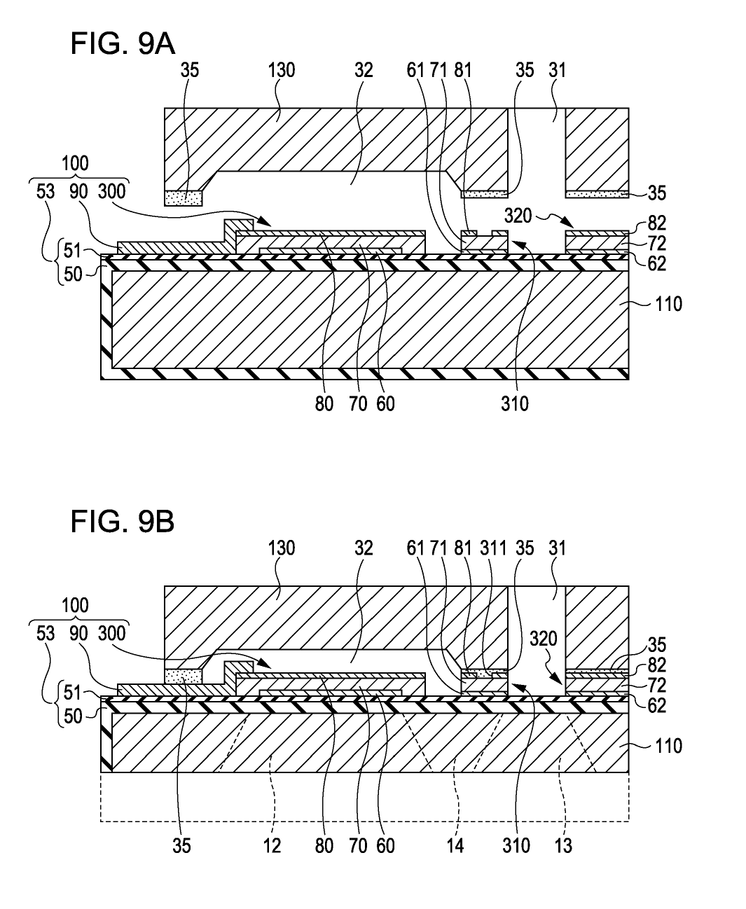

In the joining substrate joining process (S8) of FIG. 9A, a joining substrate wafer 130 which becomes a plurality of the joining substrates 30 and which is a silicon wafer is joined on the piezoelectric element 300 side of the flow path forming substrate wafer 110 using the adhesive 35. As the adhesive 35, for example, an epoxy based adhesive can be used. In the joining substrate wafer 130, the reservoir 31, the piezoelectric holding section 32 and the like are formed in advance.

In addition, since the joining substrate wafer 130 has a thickness of, for example, approximately 400 μm, the rigidity of the flow path forming substrate wafer 110 is remarkably improved by the joining of the joining substrate wafer 130.

Also, by providing the difference adjustment sections 310 and 320, it is possible to make the adhesive 35 not be thick, suppress waste due to the protrusion of the adhesive 35 and suppress the generation of stress due to the adhesive 35 being thick.

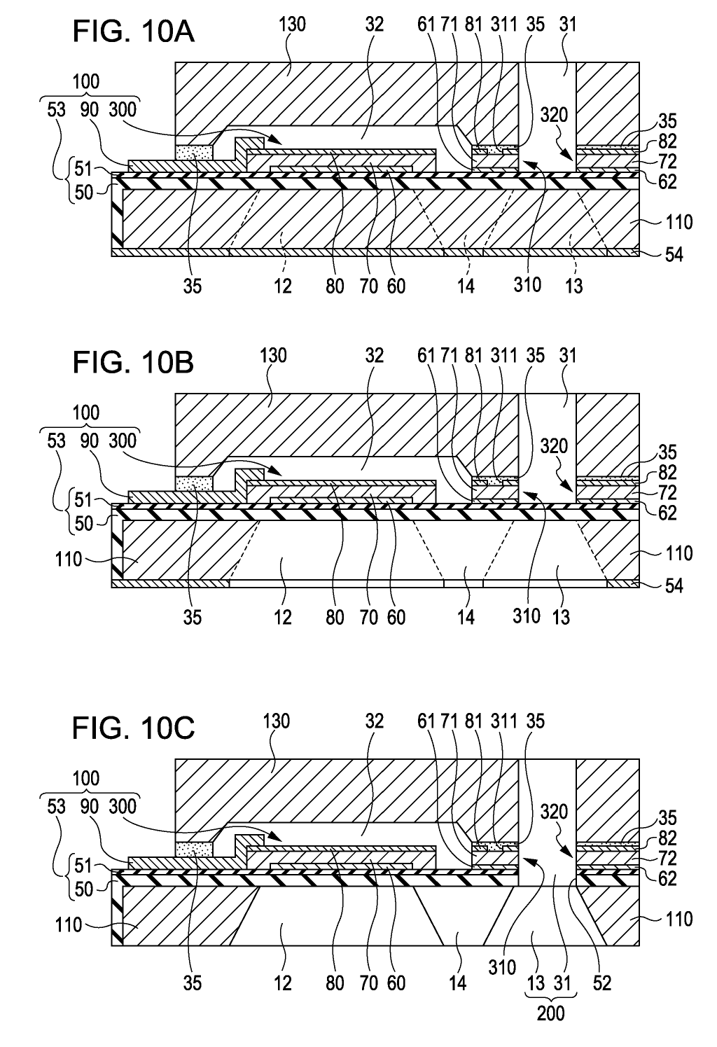

The flow path forming substrate etching process (S9) is shown in FIGS. 9B to 10C.

In FIG. 9B, after the flow path forming substrate wafer 110 is ground until it becomes a certain thickness, then the flow path forming substrate wafer 110 is made to be a predetermined thickness by performing wet etching using hydrofluoric-nitric acid. For example, it is possible to perform etching processing of the flow path forming substrate wafer 110 so that a thickness thereof becomes approximately 70 μm.

In FIGS. 10A and 10B, a mask film 54 formed from, for example, silicon nitride (SiN) is newly formed on the flow path forming substrate wafer 110 and is patterned into a predetermined shape. In addition, the pressure generating chamber 12, the communication section 14, the ink supply path 13 and the like are formed in the flow path forming substrate wafer 110 by performing anisotropic etching of the flow path forming substrate wafer 110 via the mask film 54.

Specifically, the pressure generating chamber 12, the communication section 14, the ink supply path 13 are formed at the same time by performing etching on the flow path forming substrate wafer 110 until the elastic film 50 is exposed using, for example, etching liquid such as an aqueous solution of potassium hydroxide (KOH).

In FIG. 10C, the through hole 52 is formed by removing the vibrating plate 53 formed from the elastic film 50 and the insulating film 51 from the ink supply path 13 side using wet etching. The manifold 200 is configured by the reservoir section 31 and the ink supply path 13 being communicated by the through hole 52.

Next, the mask film 54 on the surface of the flow path forming substrate wafer 110 is removed.

After the manifold 200 is formed, the driving IC 400 is mounted, and the driving IC 400 and the lead-out electrode 90 are connected by a connection wire 220 (refer to FIGS. 3A and 3B).

After this, the unnecessary portions of the periphery edge portions of the flow path forming substrate wafer 110 and the joining substrate wafer 130 are removed by, for example, cutting using dicing or the like. In addition, the nozzle plate 20 which is provided with the nozzle opening 21 is joined to the surface of the flow path forming substrate wafer 110 on the side opposite to the joining substrate wafer 130, and the compliance substrate 40, where the sealing film 41 as an elastic film with flexibility and the fixing substrate 42 as a holding substrate formed from a metallic material such as SUS are laminated, is joined to the joining substrate wafer 130.

By dividing up the flow path forming substrate wafer 110 and the like into the flow path forming substrates 10 and the like with a one chip size shown in FIGS. 2 to 3B, the ink jet recording head 1 with the configuration described above is manufactured.

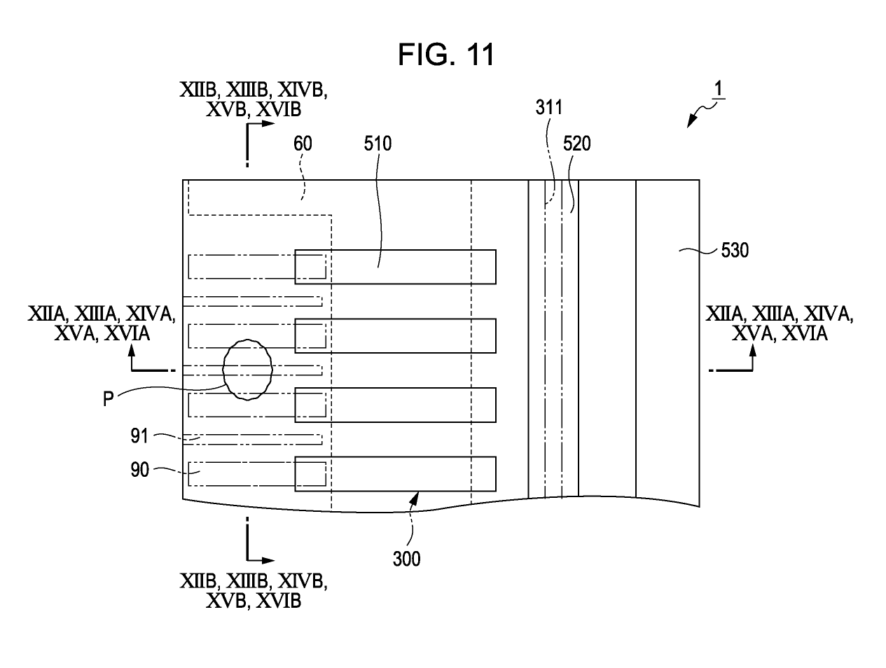

Below, in the piezoelectric element forming process (S5), the case where a particle falls from a dry etching device and is attached between the lead-out electrodes 90 formed afterwards will be described based on FIGS. 11 to 15B.

A particle, which is attached after the upper electrode film 800 is formed and before dry etching and during dry etching, becomes a particular problem. Below, the case is shown where a particle is attached after the resist films 510, 520 and 530 have been left due to development.

FIG. 11 is a partial planar diagram of a state of FIG. 6D. The lead-out electrodes 90, the slits 91, and the slit 311 to be formed afterwards are shown by dashed two-dotted lines.

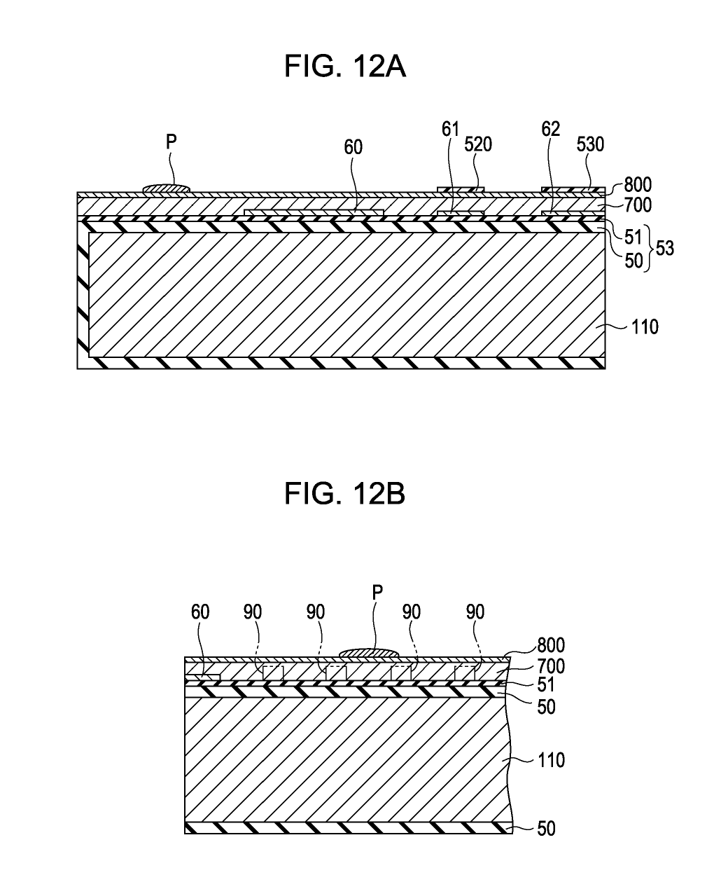

FIGS. 12A and 12B show partial cross-sectional diagrams of the state of FIG. 6D. FIG. 12A is a partial cross-sectional diagram taken along a line XIIA-XIIA of FIG. 11 and FIG. 12B is a partial cross-sectional diagram taken along a line XIIB-XIIB of FIG. 11.

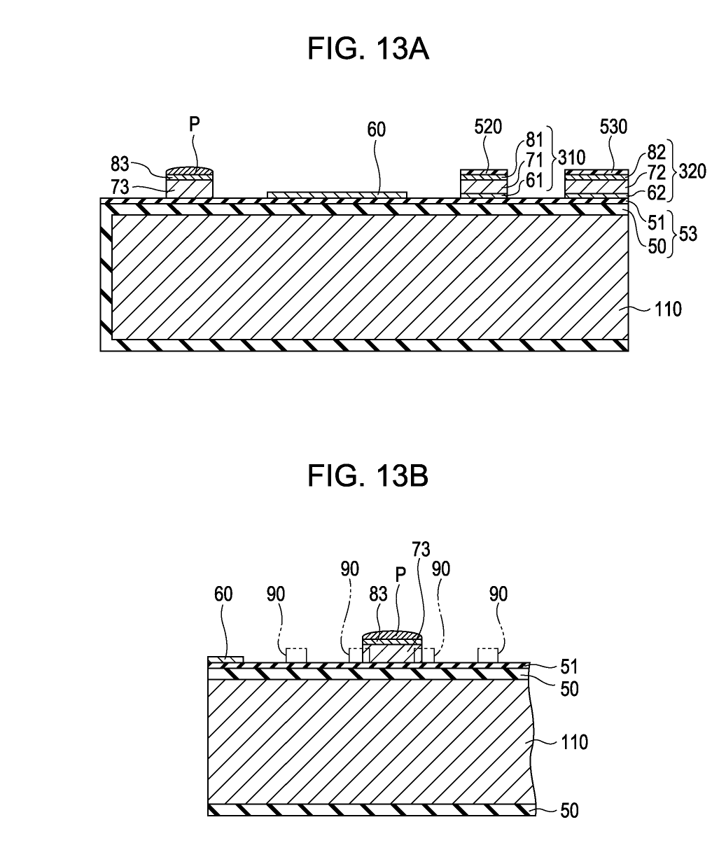

FIGS. 13A, 14A, 15A and 16A are partial cross-sectional diagrams along a line XIIIA-XIIIA (XIVA-XIVA, XVA-XVA, XVIA-XVIA) of FIG. 11 in the same manner as FIG. 12A, and FIGS. 13B, 14B, 15B and 16B are partial cross-sectional diagrams along a line XIIIB-XIIIB (XIVB-XIVB, XVB-XVB, XVIB-XVIB) of FIG. 11 in the same manner as FIG. 12B. Also, in FIGS. 12B, 13B and 14B, the positions where the lead-out electrodes 90 are to be formed are shown by dashed two-dotted lines.

In FIGS. 11 and 12B, the particle P is attached so as to span the lead-out electrodes 90 formed afterwards.

FIGS. 13A and 13B are partial cross-sectional diagrams of a state of FIG. 7A.

In FIGS. 13A and 13B, when dry etching is performed, a portion of the piezoelectric layer 700 and the upper electrode film 800 shown in FIGS. 12A and 12B where the particle P is attached leaves an etching residual, and a piezoelectric layer etching residual 73 and an upper electrode film etching residual 83 are formed.

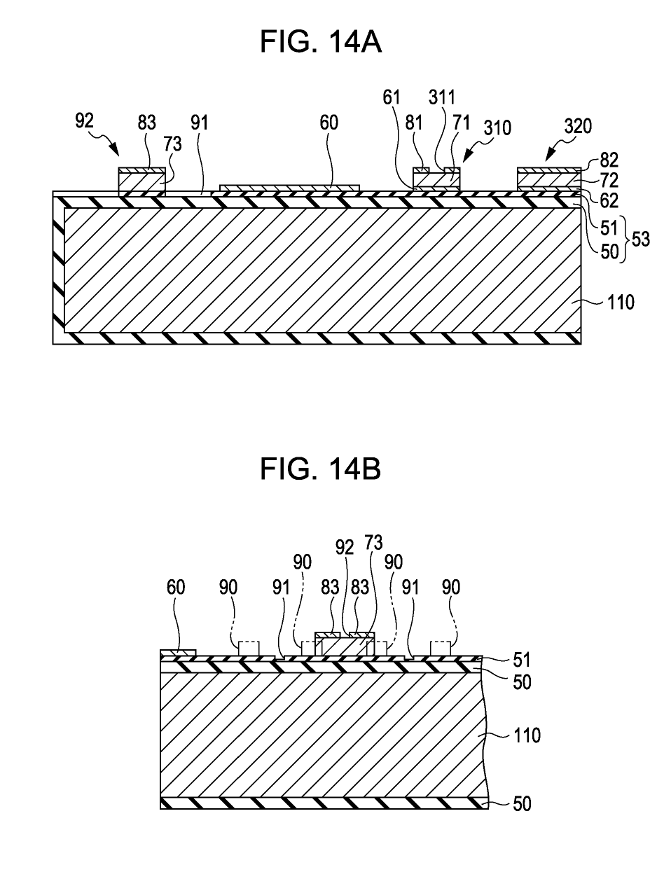

FIGS. 14A and 14B are partial cross-sectional diagrams of states of FIGS. 7C and 8A. In FIGS. 14A and 14B, when the slit 91 is simultaneously formed in the same process as the process for forming the slit 311 for reducing the stress in the upper electrode film 81 of the difference adjustment section 310, a slit 92 is also formed in the upper electrode film etching residual 83. Since the etching is performed in a condition where the upper electrode film etching residual 83 is removed, the upper electrode film etching residual 83 is divided in two by the slit 92.

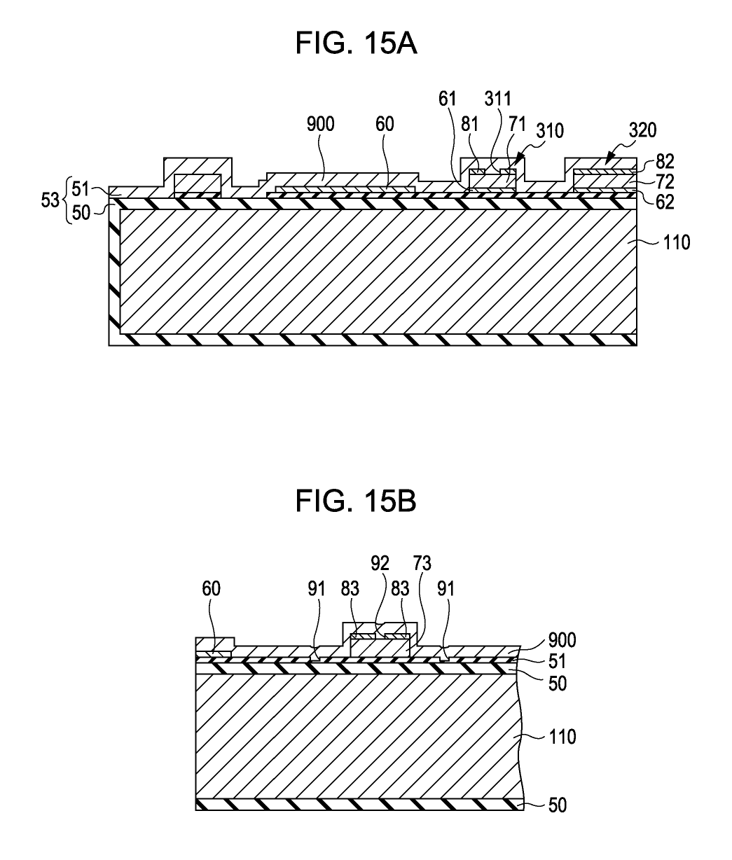

FIGS. 15A and 15B are partial cross-sectional diagrams of a state of FIG. 8B.

In FIGS. 15A and 15B, when the metallic layer 900 is formed over the entire surface of the flow path forming substrate wafer 110, the metallic layer 900 is also formed in the slits 91 and 92.

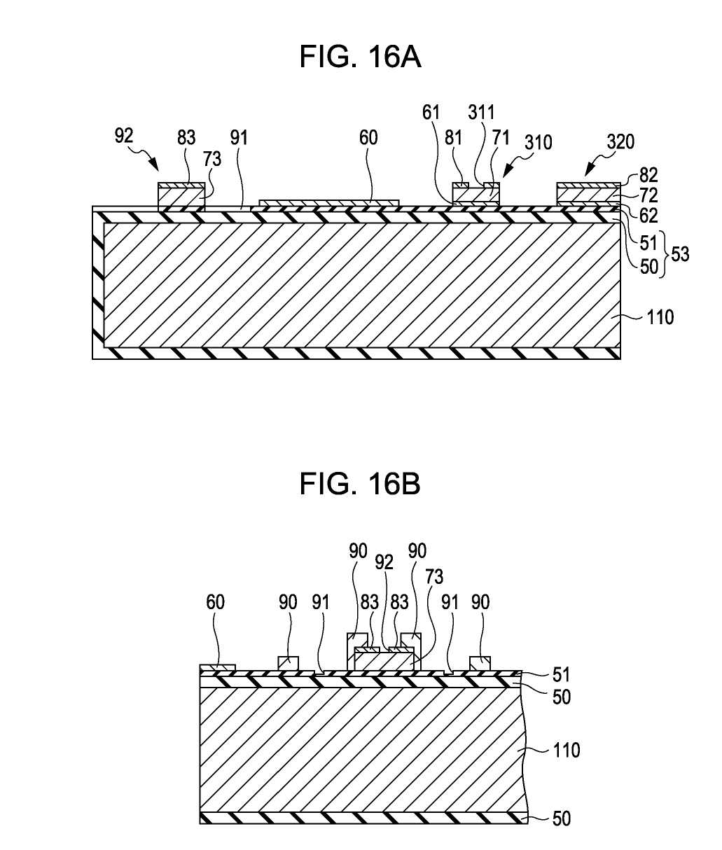

FIGS. 16A and 16B are partial cross-sectional diagrams of a state of FIG. 8C.

In FIGS. 16A and 16B, when the metallic layer 900 is patterned for each of the upper electrodes 80 which are the individual electrodes of the piezoelectric elements 300, the lead-out electrodes 90 are formed on top of the piezoelectric layer etching residual 73 and the upper electrode film etching residual 83.

According to the embodiment, there are the below effects.

(1) After the piezoelectric element forming process (S5), in the etching process (S6), etching is performed on a portion of at least the vibrating plate 53 between the lead-out electrodes 90 formed afterwards in the lead-out electrode forming process (S7) in a condition where the upper electrode film etching residual 83 is removed and the vibrating plate 53 is not removed. In the piezoelectric element forming process (S5), even if there is the upper electrode film etching residual 83 between the lead-out electrodes 90, the upper electrode film etching residual 83 is divided up due to the etching and it is possible to maintain insulation between the lead-out electrodes 90 formed in the upper electrode film etching residual 83. Accordingly, it is possible to obtain the manufacturing method of the piezoelectric actuator 100 which reduces driving defects in the piezoelectric actuator 100 generated by short circuiting between the lead-out electrodes 90.

(2) After the piezoelectric element forming process (S5), since the slits 91 and 92 are formed between the lead-out electrodes 90 along the lead-out electrodes 90, even if there is the upper electrode film etching residual 83 in any position between the lead-out electrodes 90, the upper electrode film etching residual 83 is divided up and it is possible to maintain insulation between the lead-out electrodes 90. Accordingly, it is possible to obtain the manufacturing method of the piezoelectric actuator 100 which reduces driving defects in the piezoelectric actuator 100 generated by short circuiting between the lead-out electrodes 90.

(3) In the piezoelectric actuator 100 where the lower electrode 60 formed on the vibrating plate 53 is set as the common electrode and the upper electrode 80 formed on the piezoelectric body 70 is set as the individual electrode, it is possible to obtain the manufacturing method of the piezoelectric actuator 100 having the effects described above.

It is also possible to perform various modifications other than the embodiment.

For example, after the piezoelectric element forming process (S5), a protective layer may be formed to protect the exposed piezoelectric body from moisture and the like. As the protective layer, for example, Al₂O₃ can be used. The etching process (S6) may be performed before the protective layer is formed or after the protective layer is formed. Even if there are pin holes or the like in the protective layer, it is possible to obtain the effects of the embodiment. In the case where the upper electrode is set as the common electrode, the upper electrode functions as the protective layer and there is little necessity to newly form the protective layer.

Also, in the embodiment described above, description is made with the ink jet recording head used as an example of a liquid ejecting head. However, the invention is broadly intended for all liquid ejecting heads and of course can also be applied to liquid ejecting heads which eject a liquid other than ink.

As other liquid ejecting heads, for example, there are various types of recording heads used in image recording apparatuses such as printers and the like, coloring material ejecting heads used in the manufacturing of color filters for liquid crystal displays and the like, electrode material ejecting heads used in forming electrodes for organic EL displays, FEDs (field emission displays) and the like, bioorganic material ejecting heads used in manufacturing biochips, and the like.

In addition, it can be applied to not only a piezoelectric actuator mounted in a liquid ejecting head as a pressure generating unit but also piezoelectric actuators mounted in various devices. For example, the piezoelectric actuator can also be applied to sensors and the like other than heads described above.

What is claimed is:

1. A manufacturing method of a piezoelectric actuator provided with a piezoelectric element, which has either a lower electrode or an upper electrode as an individual electrode, and a lead-out electrode led-out from the individual electrode comprising:
forming a lower electrode film on a substrate,
forming a piezoelectric layer on the lower electrode film,
forming an upper electrode film on the piezoelectric layer,
forming a piezoelectric element with a piezoelectric body and either of the lower electrode or the upper electrode provided as an individual electrode by selectively etching on the piezoelectric layer and the lower electrode film or the upper electrode film,
etching of at least a portion of the substrate between the lead-out electrodes in a condition where the upper electrode film is removed and the substrate is not removed after the forming of the piezoelectric element, and
forming the lead-out electrode led-out from the individual electrode after the etching of at least a portion of the substrate.

2. The manufacturing method of a piezoelectric actuator according to claim 1:
wherein, in the etching of at least a portion of the substrate, etching between the lead-out electrodes is performed along the lead-out electrodes and a slit is formed in the substrate.

3. The manufacturing method of a piezoelectric actuator according to claim 1:
wherein, the lower electrode is formed on the substrate as a common electrode in the forming of the piezoelectric element, and
etching is selectively performed on the piezoelectric layer and the upper electrode film, whereby the piezoelectric element is formed with a piezoelectric body and the upper electrode provided as the individual electrode.
